(19) United States
(12) Patent Application Publication
(10) Pub. No.: US 2006/0017515 A1
(43) Pub. Date: Jan. 26, 2006

(54) CMOS negative resistance/Q enhancement method and apparatus

(75) Inventors: Nebojsa Stanic, New York, NY (US); Yannis Tsividis, New York, NY (US)

Correspondence Address: WILMER CUTLER PICKERING HALE AND DORR LLP;COLUMBIA UNIVERSITY, 399 PARK AVENUE, NEW YORK, NY, 10020, US

(73) Assignee: Columbia University

(21) Appl. No.: 10/896,758

(22) Filed: Jul. 22, 2004

(51) Int. Cl. H03B 5/12

(52) U.S. Cl. 331/117 R

(57) ABSTRACT

An apparatus for optimizing a quality factor Q associated with an electrical resonator system includes an LC resonator and an optimizing circuit for providing a negative resistance. The optimizing circuit is electrically coupled to the resonator circuit, and includes two CMOS transistor pairs with the gates of the PMOS transistors cross-coupled with inputs to the resonator through capacitors, and the gates of the NMOS transistor cross-coupled with the inputs to the resonator through capacitors. The optimizing circuit receives at least one control voltage for varying the negative resistance by selectively biasing the PMOS transistors and NMOS transistors. The optimizing circuit also includes a current source for providing a controlled current to the CMOS transistor pairs. The current source is situated either between a supply voltage and the CMOS transistor pairs, or between the CMOS transistor pairs and a ground reference voltage. A current-control voltage controls the current flowing through the CMOS transistor pairs.

### BACKGROUND OF THE INVENTION

The present invention relates to negative resistance circuits, and more particularly, to Q enhancement of LC filters and resonators using tuning circuits that incorporate a negative resistance.

A circuit that realizes a negative resistance has many useful applications. For example, in a practical LC filter or resonator circuit, the inductor L is lossy to some extent. This loss may be modeled as a real, positive resistance component in series with the pure inductance component of the physical inductor. The quality factor (referred to herein as “Q”) of the LC filter or resonator is inversely proportional to this loss, i.e., the Q decreases as the resistance value increases. It is well known in the art to combine a negative resistance with the inductor to reduce or eliminate the loss component, thereby optimizing the Q.

LC resonators fabricated on analog integrated circuits (ICs) typically do not exhibit a predictable Q. The processing variations of commercial IC processes produce inductors with loss values that can vary over a wide range, resulting in a correspondingly wide range of Q. A negative resistance circuit used in conjunction with an LC resonator on an IC may be used to optimize the resonator's Q. The negative resistance circuit may also optimize the resonator's Q with respect to resonator variations due to parasitics and temperature changes.

FIG. 1 shows one example of a prior art negative resistance circuit used in conjunction with an LC filter design. The negative resistance circuit consists of a single pair of cross-connected transistors M1 and M2, and a current source M3. Although the current source M3 is shown between the source voltage Vdd and the inductors, the current source M3 in some cases may be equivalently disposed between the cross-connected transistors and ground. The negative resistance Rn applied in parallel to the LC resonator is given by:
Rn=−2/Gm
where Gm is the transconductance of the transistors M1 and M2.

FIG. 2 shows another type of prior art negative resistance circuit, with two differential pairs of transistors, connected in parallel with the same LC resonator.

To compare the performance of the circuits of FIGS. 1 and 2, assume that all the transistors in these two circuits are square law devices, and that they operate in saturation. Transistors manufactured in modern processes do not behave according to the square law, but the following analysis gives insight in, and shows the correct trend of, the circuit behavior.

Consider the simple differential pair of transistors first, shown in the FIG. 3, biased with the current source with dc current I, and with an input voltage Vs between gates of the transistors given by V1-V2. Solving the circuit for the current i1, and expanding i1 into a Taylor series gives:

$$i1 = \frac{I}{2} ( 1 + ( \frac{Vs}{Δ Vgs} ) - \frac{1}{8} {( \frac{Vs}{Δ Vgs} )}^{3} )$$

neglecting the fifth order and higher terms in the series, and letting ΔVgs=Vgs−Vt, with Vt being the transistor threshold voltage.

These equations provide a measure of the linearity of the negative resistance circuits in FIGS. 1 and 2. The comparison is valid assuming that the LC resonators and the dc biasing currents I in both circuits are the same.

The transconductance of each of the transistors in saturation is given by:
Gm=2*(I/2)/ΔVgs

Since the negative resistance applied to the LC resonator in both circuits must be the same for a valid comparison, the total Gm needed in both circuits is also the same. Assume that in the CMOS negative resistance (i.e., FIG. 2), half of the total Gm comes from the PMOS transistors and half from the NMOS transistors. Under these assumptions,

Δ Vgsn=2*(I/2)/Gm, for the transistors M1-2 in NMOS circuit (FIG. 1), and

ΔVgsc=2*(I/2)/(Gm/2), for the transistors M1-4 in the CMOS circuit (FIG. 2),

where ΔVgsc is the absolute value of the voltages ΔVgs on the PMOS and NMOS side of the circuit. It follows that:
ΔVgsc=2*ΔVgsn.

Combining this last equation with the expression for the current in the differential pair of the transistors provides a way to compare the linearity of the two circuits. The linear, first order term in the Taylor series represents the total Gm applied to the resonator, which by the original assumption is the same for the NMOS and CMOS circuit. The third order term is a measure of the nonlinearity of the circuits; the greater it is relative to the linear term, the more nonlinear the circuit is.

For the CMOS circuit, the third order term is:

$$\begin{matrix}2 * \frac{1}{8} * {( \frac{Vs}{Δ Vgsc} )}^{3} = 2 * \frac{1}{8} * {( \frac{Vs}{2 * Δ Vgsn} )}^{3} \\ = \frac{1}{4} * \frac{1}{8} * {( \frac{Vs}{Δ Vgsn} )}^{3}\end{matrix}$$

where factor of 2 is a result of summing the nonlinear terms on the NMOS and PMOS sides of the CMOS circuit.

For the NMOS circuit, the third order term is:

$$1 * \frac{1}{8} * {( \frac{Vs}{Δ Vgsn} )}^{3}$$

Since the third order term for the CMOS circuit of FIG. 2 is smaller than the third order term of the NMOS circuit of FIG. 1, the CMOS negative resistance will be more linear than the NMOS negative resistance for the same biasing current I and for the same choice of the LC resonator.

The current trend of technology scaling in analog ICs drives the supply voltage Vdd to lower and lower values. Reducing Vdd in the circuit of FIG. 2, however, also reduces ΔVgs. Use of the negative resistance circuit of FIG. 2 therefore requires an undesirable tradeoff between low non-linearity and high ΔVgs.

What is needed is a negative resistance circuit having the superior linearity characteristics of the circuit shown in FIG. 2, as compared to the widely used single transistor pair negative resistance of FIG. 1, but does not sacrifice ΔVgs as the supply voltage drops.

### SUMMARY OF THE INVENTION

An apparatus for optimizing a quality factor Q associated with an electrical resonator system includes a resonator circuit and an optimizing circuit for providing a negative resistance. As used herein, the term “optimizing” is with respect to a particular purpose, and does not necessarily refer to a best result in absolute terms. In some cases the quality factor Q may need to be balanced against certain tradeoffs with respect to the circuit or overall system, such that an optimal quality factor may not necessarily be the absolute best quality factor Q under all circumstances. For example, if attaining absolute maximum quality factor of a filter sacrifices other desired filter characteristics, a circuit designer may wish to accept less than the absolute best quality factor to improve the other desired filter characteristics. In general, the apparatus improves the quality factor to some extent, and in doing so considers other factors related to the surrounding circuits and system.

The resonator circuit includes an inductor and a capacitor, and the optimizing circuit is electrically coupled to the resonator circuit, and includes at least two transistors cross-coupled with inputs to the resonator through capacitors. The optimizing circuit receives at least one control voltage for varying the negative resistance.

One embodiment of the optimizing circuit includes a first transistor (NMOS type) and a second transistor (PMOS type) (a first transistor pair), and a third transistor (NMOS type) and a fourth transistor (PMOS type) (a second transistor pair). Each transistor pair is arranged in a CMOS configuration. The resonator is electrically coupled between a drain coupling of the first CMOS transistor pair and a drain coupling of the second transistor pair.

A gate of the PMOS transistor from the first pair of transistors and a gate of the PMOS transistor from the second pair of transistors are capacitively cross-coupled with inputs to the resonator. A control voltage biases the gate of the PMOS transistor of the first pair of transistors through a first bias resistor, and the gate of the PMOS transistor of the second pair of transistors through a second bias resistor. Although not shown in the figures for this embodiment, the optimizing circuit may employ a separate biasing voltage for each of the PMOS transistors. A gate of the PMOS transistor from the first pair of transistors is capacitively coupled to a ground reference voltage, and a gate of the PMOS transistor from the second pair of transistors is capacitively coupled to the ground reference voltage.

A gate of the NMOS transistor from the first pair of transistors and a gate of the NMOS transistor from the second pair of transistors are capacitively cross-coupled with inputs to the resonators. A second control voltage biases the gate of the NMOS transistor of the first pair of transistors through a third bias resistor, and the gate of the NMOS transistor of the second pair of transistors through a fourth bias resistor. Although not shown in the figures for this embodiment, the optimizing circuit may employ a separate biasing voltage for each of the NMOS transistors. A gate of the NMOS transistor from the first pair of transistors is capacitively coupled to a ground reference voltage, and a gate of the NMOS transistor from the second pair of transistors is capacitively coupled to the ground reference voltage.

The optimizing circuit also includes a current source for providing a controlled current to the transistors in the CMOS configuration. The current source includes a fifth transistor electrically coupled in series with the transistor pairs in the CMOS configuration, between a supply voltage and a ground reference voltage, so that a current-control voltage applied to the fifth transistor controls current flowing through the transistor pairs in the CMOS configuration.

A method of optimizing a quality factor Q associated with an electrical resonator system includes providing a negative resistance, generated by an optimizing circuit, electrically coupled to a resonator circuit. The resonator circuit includes an inductor and a capacitor, and the optimizing circuit includes at least one pair of NMOS or one pair PMOS transistors with gates cross-coupled with inputs to the resonator through capacitors. The method further includes adjusting one or more control voltages applied to the optimizing circuit so as to substantially optimize the quality factor Q associated with the resonator circuit. The method further includes measuring the quality factor Q and providing a control system that adjusts the one or more control voltages as a function of the measured Q

A circuit for providing a negative resistance across a first input and a second input includes a first CMOS transistor pair arranged in parallel with a second CMOS transistor pair, and a current source for controlling the current flowing through the transistor pairs in the CMOS configurations. The first CMOS transistor pair is capacitively cross-coupled with the first and second inputs, and includes a first PMOS transistor and a first NMOS transistor with their drains electrically connected. The second CMOS transistor pair is capacitively cross-coupled with the first and second input, and includes a second PMOS transistor and a second NMOS transistor with their drains electrically connected. The second CMOS pair is arranged in parallel with the first CMOS pair such that the source of the first PMOS transistor is electrically coupled to the source of the second PMOS transistor, and the source of the first NMOS transistor is electrically coupled to the source of the second NMOS transistor, and also to a ground reference voltage. A first biasing voltage controls the PMOS transistors, and a second biasing voltage controls the NMOS transistors. The current source is electrically coupled between a supply voltage and the sources of the PMOS transistors, such that a current-control voltage applied to the current source controls current flowing through the transistor pairs in the CMOS configuration. The current source may be located between the CMOS transistors and ground, rather than between the supply voltage and the CMOS transistors.

In another embodiment, a circuit for providing a negative resistance across a first input and a second input includes a first CMOS transistor pair, a second CMOS transistor pair and a current source for controlling the current flowing through the CMOS transistor pairs. The first CMOS transistor pair includes a first PMOS transistor and a first NMOS transistor electrically connected at their drains. A second CMOS transistor pair includes a second PMOS transistor and a second NMOS transistor electrically connected at their drains. The second CMOS pair is arranged in parallel with the first CMOS pair with the sources of the PMOS transistors connected and the sources of the NMOS transistors connected. The sources of the NMOS transistors are also connected to a ground reference voltage. The current source includes a current source transistor electrically coupled between a supply voltage and the sources of the PMOS transistors, so that a source control voltage applied to the fifth transistor controls current flowing through the transistor pairs in the CMOS configuration. The first input is electrically coupled to the drain coupling of the first transistor pair, and the second input is electrically coupled to the drain coupling of the second transistor pair. The gates of the first PMOS transistor and the second PMOS transistor are capacitively cross-coupled with the first input and the second input, and the gates of the first NMOS transistor and the second NMOS transistor are capacitively cross-coupled with the first input and the second input. A first control voltage biases the first PMOS transistor through a first bias resistor, and the first control voltage biases the second PMOS transistor through a second bias resistor. A second control voltage biases the first NMOS transistor through a first bias resistor, and the second control voltage biases the second NMOS transistor through a second bias resistor. Each of the first and second PMOS transistors and the first and second NMOS transistor includes a gate capacitively coupled to the ground reference voltage. The current source may be located between the CMOS transistors and ground, rather than between the supply voltage and the CMOS transistors.

An apparatus for optimizing a quality factor Q associated with an electrical resonator system may further include an apparatus for measuring the Q and a controller for receiving the measured Q and generating the biasing voltages that control the negative resistance therefrom.

### BRIEF DESCRIPTION OF THE DRAWINGS

The foregoing and other objects of this invention, the various features thereof, as well as the invention itself, may be more fully understood from the following description, when read together with the accompanying drawings in which:

FIG. 1 shows one example of a prior art negative resistance circuit used in conjunction with an LC filter design;

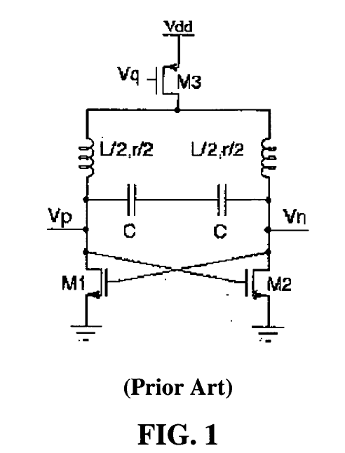

FIG. 2 shows another type of prior art negative resistance circuit;

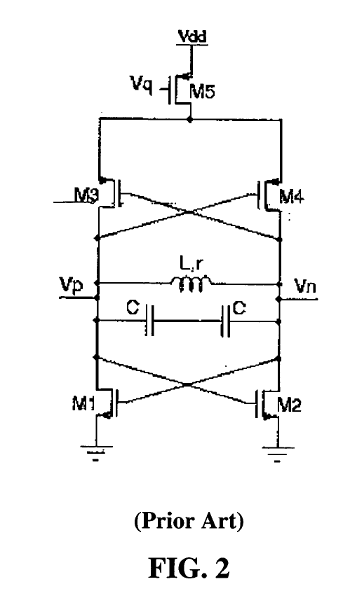

FIG. 3 shows a prior art differential pair of transistors;

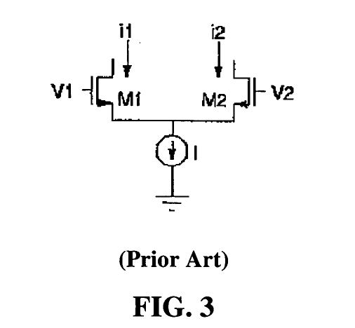

FIG. 4 shows a block diagram view of new CMOS negative resistance circuit with an associated resonator;

FIG. 5 shows a more detailed view of the CMOS negative resistance circuit shown in FIG. 4; and,

FIG. 6 shows a Q measuring circuit and a controller connected to the CMOS negative resistance circuit and LC resonator of FIG. 4.

### DESCRIPTION OF THE PREFERRED EMBODIMENTS

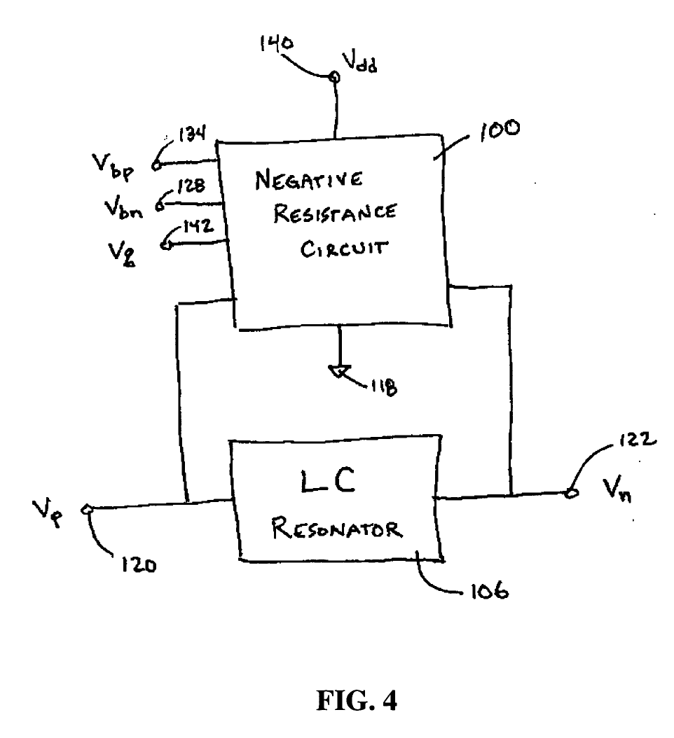

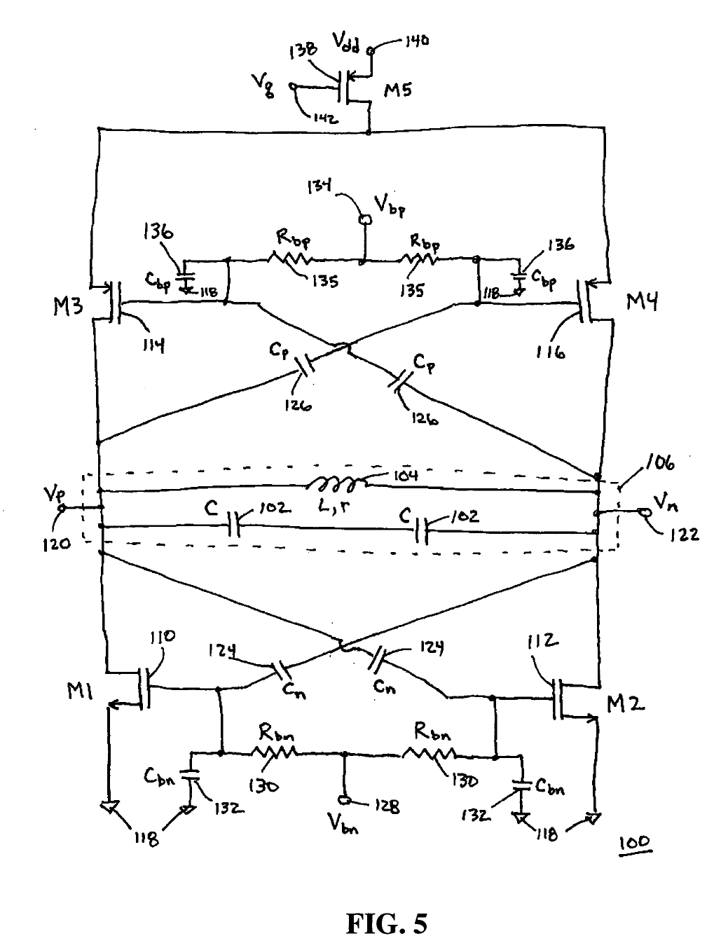

One embodiment of a CMOS negative resistance circuit 100 is shown in FIG. 4, coupled in parallel to an LC resonator 106. FIG. 5 shows an expanded view of the negative resistance circuit 100 and the LC resonator 106 of FIG. 4. The capacitor C 102 and the inductor L 104 form a parallel LC resonator 106. The inductor 104 is a lossy device; the lossy component is typically modeled as a resistance connected in series with the inductance. FIG. 5 shows the presence of that resistance via the “r” in the inductor symbol. The remaining components in FIG. 5 represent a negative resistance circuit applied to the resonator to cancel the loss. M1 110 and M2 112 are NMOS transistors; M3 114 and M4 116 are PMOS transistors. The drains of M1 110 and M3 114 are electrically coupled together (referred to herein as a “drain coupling” of these transistors), and the drains of M2 112 and M4 116 are electrically coupled together. The sources of M3 114 and M4 116 are electrically coupled together, and the sources of M1 110 and M2 112 are electrically coupled to ground 118.

Connections Vp 120 and Vn 122 provide a differential AC input signal to the resonator 106. Capacitors Cn 124 and Cp 126 pass the AC signal from the differential input to the gates of the NMOS transistors M1 110 and M2 112, and to the gates of the PMOS transistors M3 114 and M4 116. This arrangement of coupling an input signal taken from parallel current paths through capacitors to the gates of transistors in those parallel current paths is referred to herein as “capacitive cross-coupling,” and allows the circuit to apply a negative resistance looking from the input.

A DC biasing voltage Vbn 128 biases the gates of the NMOS transistors M1 110 and M2 112 through a pair of biasing resistors Rbn 130, and a pair of capacitors Cbn 132 decouples each of the gates of NMOS transistors M1 110 and M2 112 to ground 118. The DC biasing voltage Vbp 134 biases the gates of the PMOS transistors M3 114 and M4 116 through a pair of biasing resistors Rbp 135, and a pair of capacitors Cbp 136 decouples each of the gates of the PMOS transistors M3 114 and M4 116 to ground 118. Although not shown in FIG. 5, each of the NMOS transistors M1 110 and M2 112 and the PMOS transistors M3 114 and M4 116 may each be biased by an individual biasing voltage dedicated to one particular transistor.

A transistor M5 138, electrically coupled between Vdd 140 and the sources of transistor M3 114 and transistor M4 116, provides a controlled current source for the rest of the negative resistance circuit 100. The source of transistor M5 138 is electrically coupled to Vdd 140, the drain of transistor M5 138 is electrically coupled to sources of transistor M3 114 and transistor M4 116, and the gate of transistor M5 138 is electrically coupled to control voltage Vq 142. Varying the control voltage Vq 142 correspondingly varies the dc current through transistor M5 138 and consequently through the rest of the negative resistance circuit 100. This DC current controls the transconductance of the transistors M1 110, M2 112, M3 114 and M4 116, which in turn determines the amount of negative resistance the circuit 100 applies to the resonator 106. The DC voltages at the midpoints Vp 120 and Vn 122, and at the drain of the transistor M5 138 vary as the DC current varies through transistor M5 138.

Some embodiments of the negative resistance circuit 100 may include additional circuitry (not shown), including but not limited to a negative resistance replica circuit and DC negative feedback loops, to set the Vp, Vn and transistor M5 138 drain DC voltages to desired values for correct circuit function. The structure of such additional circuitry varies widely and is well known in the art.

Capacitors Cp 126 and Cn 124 isolate the gates of the associated transistors for dc signal from the inputs Vp 120 and Vn 122, which allows biasing voltage Vbn 128 to be higher than, and biasing voltage Vbp 134 to be lower than, the dc voltage level at the differential inputs Vp 120 and Vn 122. This arrangement allows for control of the Vgs between gate and source of each of transistors M1 110, M2 112, M3 114 and M4 116, independent of the voltage at the differential input Vp 120 and Vn 122, and of the supply voltage Vdd 140. Such control of Vgs corresponds control of ΔVgs, which means that increasing Vbp 134 and Vbn 128 increases the absolute value of the negative resistance. Consequently the circuit of FIG. 5 provides the superior linearity characteristics of a negative resistance circuit with CMOS topology without sacrificing a desirable high ΔVgs.

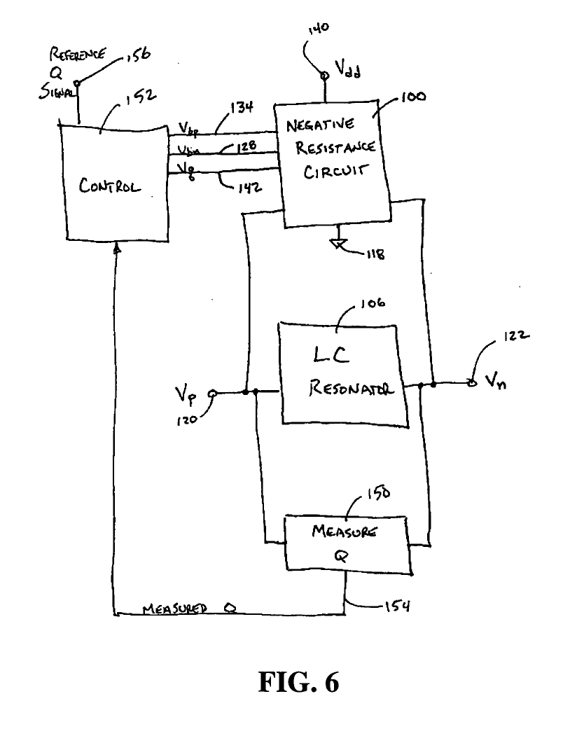

FIG. 6 shows a Q measuring circuit 150 and a controller 152 connected to the CMOS negative resistance circuit 100 and LC resonator 106 of FIG. 4. The Q measuring circuit measures the Q the resonator 106 exhibits and produces a measured Q signal corresponding to that measurement. The Q measuring circuit may utilize any one of several techniques of measuring a Q value known in the art. The controller 152 receives the measured Q signal 154 and a reference Q signal 156, and sets the values of Vbp 134, Vbn 128 and Vq 142 as a function of the measured Q so as to adjust the Q of the resonator 106 commensurate with the desired reference Q signal.

The invention may be embodied in other specific forms without departing from the spirit or essential characteristics thereof. The present embodiments are therefore to be considered in respects as illustrative and not restrictive, the scope of the invention being indicated by the appended claims rather than by the foregoing description, and all changes which come within the meaning and range of the equivalency of the claims are therefore intended to be embraced therein.

What is claimed is:

1. An apparatus comprising:
a resonator circuit including at least an inductor and a capacitor;
an optimizing circuit for providing a negative resistance, wherein the optimizing circuit (i) is electrically coupled to the resonator circuit, and (ii) includes at least two NMOS transistors or two PMOS transistors capacitively cross-coupled with the resonator circuit.

2. An apparatus according to claim 1, wherein the optimizing circuit receives at least one control voltage for selectively biasing one or more of the transistors and varying the negative resistance.

3. An apparatus according to claim 1, wherein the at least one pair of transistors is cross-coupled with inputs to the resonator.

4. An apparatus according to claim 1, wherein the optimizing circuit includes a first PMOS transistor and a first NMOS transistor being a first transistor pair, and a second PMOS transistor and a second NMOS transistor being a second transistor pair, each transistor pair arranged in a CMOS configuration, wherein the resonator is electrically coupled between a drain coupling of the first transistor pair and a drain coupling of the second transistor pair.

5. An apparatus according to claim 4, wherein a PMOS transistor from the first pair of transistors and a PMOS transistor from the second pair of transistors are capacitively cross-coupled with inputs to the resonator.

6. An apparatus according to claim 4, wherein a first control voltage biases a PMOS transistor from the first pair of transistors through a first bias resistor, and a second control voltage biases a PMOS transistor from the second pair of transistors through a second bias resistor.

7. An apparatus according to claim 6, wherein the first control voltage and the second control voltage are substantially equal.

8. An apparatus according to claim 6, wherein a gate of the PMOS transistor from the first pair of transistors is capacitively coupled to a ground reference voltage, and a gate of the PMOS transistor from the second pair of transistors is capacitively coupled to the ground reference voltage.

9. An apparatus according to claim 4, wherein an NMOS transistor from the first pair of transistors and an NMOS transistor from the second pair of transistors are capacitively cross-coupled with inputs to the resonator.

10. An apparatus according to claim 4, wherein a first control voltage biases an NMOS transistor from the first pair of transistors through a first bias resistor, and a second bias voltage biases an NMOS transistor from the second pair of transistors through a second bias resistor.

11. An apparatus according to claim 10, wherein the first control voltage and the second control voltage are substantially equal.

12. An apparatus according to claim 10, wherein a gate of the NMOS transistor from the first pair of transistors is capacitively coupled to a ground reference voltage, and a gate of the NMOS transistor from the second pair of transistors is capacitively coupled to the ground reference voltage.

13. An apparatus according to claim 4, further including a current source for providing a controlled current to the transistors in the CMOS configuration.

14. An apparatus according to claim 13, wherein the current source includes a fifth transistor electrically coupled in series with the transistor pairs in the CMOS configuration between a supply voltage and a ground reference voltage, such that a current-control voltage applied to the fifth transistor controls current flowing through the transistor pairs in the CMOS configuration.

15. An apparatus for optimizing a quality factor Q associated with an electrical resonator system, comprising:
a resonator circuit including at least an inductor and a capacitor;
an optimizing circuit for providing a negative resistance, wherein the optimizing circuit (i) is electrically coupled to the resonator circuit, and (ii) includes a first PMOS transistor and a first NMOS transistor being a first transistor pair, and a second PMOS transistor and a second NMOS transistor being a second transistor pair, each transistor pair arranged in a CMOS configuration, wherein the resonator is electrically coupled between the drains of the first transistor pair and the second transistor pair;
a current source including a fifth transistor electrically coupled in series with the transistors in the CMOS configuration between a supply voltage and a ground reference voltage, such that a first control voltage applied to the fifth transistor controls current flowing through the transistors in the CMOS configuration
wherein a PMOS transistor from the first pair of transistors and a PMOS transistor from the second pair of transistors are capacitively cross-coupled with inputs to the resonator, a second control voltage biases the PMOS transistor from the first pair of transistors through a first bias resistor, and the second control voltage biases the PMOS transistor from the second pair of transistors through a second bias resistor;
wherein an NMOS transistor from the first pair of transistors and an NMOS transistor from the second pair of transistors are capacitively cross-coupled with inputs to the resonator, a third control voltage biases the NMOS transistor from the first pair of transistors through a third bias resistor, and the third control voltage biases the NMOS transistor from the second pair of transistors through a fourth bias resistor; and,
each of the gates of the transistors in the CMOS configuration are capacitively coupled to a ground reference voltage.

16. A method of optimizing a quality factor Q associated with an electrical resonator system, comprising:
providing a resonator circuit including at least an inductor and a capacitor;
providing a negative resistance via an optimizing circuit, wherein the optimizing circuit (i) is electrically coupled to the resonator circuit through capacitors; and,
adjusting one or more control voltages applied to the optimizing circuit so as to improve the quality factor Q associated with the resonator circuit.

17. A method according to claim 16, further including measuring the quality factor Q so as to produce a measured Q, and providing a control system for adjusting the one or more control voltages as a function of the measured Q.

18. A method according to claim 16, further including cross-coupling at least two transistors with inputs to the resonator.

19. A method according to claim 16, further including providing, as part of the optimizing circuit, a first PMOS transistor and a first NMOS transistor being a first transistor pair, and a second PMOS transistor and a second NMOS transistor being a second transistor pair, each transistor pair arranged in a CMOS configuration, wherein the resonator is electrically coupled between the drains of the first transistor pair and the second transistor pair.

20. A method according to claim 19, further including capacitively cross-coupling a PMOS transistor from the first pair of transistors and a PMOS transistor from the second pair of transistors with inputs to the resonator.

21. A method according to claim 19, further including biasing a PMOS transistor from the first pair of transistors with a first control voltage through a first bias resistor, and biasing a PMOS transistor from the second pair of transistors with a second control voltage through a second bias resistor.

22. A method according to claim 21, further including setting the first control voltage substantially equal to the second control voltage.

23. A method according to claim 21, further including capacitively coupling a gate of the PMOS transistor from the first pair of transistors to a ground reference voltage, and capacitively coupling a gate of the PMOS transistor from the second pair of transistors to the ground reference voltage.

24. A method according to claim 19, further including capacitively cross-coupling an NMOS transistor from the first pair of transistors and an NMOS transistor from the second pair of transistors with inputs to the resonator.

25. A method according to claim 19, further including biasing an NMOS transistor from the first pair of transistors with a first control voltage through a first bias resistor, and biasing an NMOS transistor from the second pair of transistors with a second control voltage through a second bias resistor.

26. A method according to claim 25, further including setting the first control voltage substantially equal to the second control voltage.

27. A method according to claim 25, further including capacitively coupling a gate of the NMOS transistor from the first pair of transistors to a ground reference voltage, and capacitively coupling a gate of the NMOS transistor from the second pair of transistors to the ground reference voltage.

28. A method according to claim 19, further including providing a controlled current to the transistors in the CMOS configuration.

29. A method according to claim 28, further including electrically coupling a fifth transistor in series with the transistor pairs in the CMOS configuration between a supply voltage and a ground reference voltage, such that a control voltage applied to the fifth transistor controls current flowing through the transistors in the CMOS configuration.

30. A method of optimizing a quality factor Q associated with an electrical resonator system, comprising:
providing a resonator circuit including at least an inductor and a capacitor;
providing a negative resistance via an optimizing circuit, electrically coupling the optimizing circuit to the resonator circuit, and including in the optimizing circuit a first transistor and a second transistor being a first transistor pair, and a third transistor and a fourth transistor being a second transistor pair, arranging each transistor pair in a CMOS configuration, and electrically coupling the resonator between the drains of the first transistor pair and the second transistor pair;
providing a current source including a fifth transistor electrically coupled in series with the transistors in the CMOS configuration between a supply voltage and a ground reference voltage, such that a first control voltage applied to the fifth transistor controls current flowing through the transistors in the CMOS configuration
capacitively cross-coupling a PMOS transistor from the first pair of transistors and a PMOS transistor from the second pair of transistors with inputs to the resonator, biasing the PMOS transistor from the first pair of transistors with a second control voltage through a first bias resistor, and biasing the PMOS transistor from the second pair of transistors with the second control voltage through a second bias resistor;
capacitively cross-coupling an NMOS transistor from the first pair of transistors and an NMOS transistor from the second pair of transistors with inputs to the resonator, biasing the NMOS transistor from the first pair of transistors with a third control voltage through a first bias resistor, and biasing the NMOS transistor from the second pair of transistors with the third bias voltage through a second bias resistor; and,
capacitively coupling each of the gates of the transistors in the CMOS configuration to a ground reference voltage.

31. A circuit for providing a negative resistance across a first input and a second input, comprising:
a first CMOS transistor pair cross-coupled with the first and second inputs, including a first PMOS transistor and a first NMOS transistor electrically connected at a drain coupling;
a second CMOS transistor pair cross-coupled with the first and second input, including a second PMOS transistor and a second NMOS transistor electrically connected at a drain coupling, the second CMOS pair being arranged in parallel with the first CMOS pair such that a source of the first PMOS transistor is electrically coupled to a source of the second PMOS transistor, and a source of the first NMOS transistor is electrically coupled to a source of the second NMOS transistor and to a ground reference voltage;
a first biasing voltage for biasing the PMOS transistors, and a second biasing voltage for biasing the NMOS transistors; and,
a current source electrically coupled between a supply voltage and the sources of the PMOS transistors, such that a current-control voltage applied to the current source controls current flowing through the transistor pairs in the CMOS configuration.

32. A circuit according to claim 31, wherein the current source is electrically coupled between the sources of the NMOS transistors and a ground reference voltage, and the supply voltage is electrically coupled to the sources of the PMOS transistors.

33. A circuit for providing a negative resistance across a first input and a second input, comprising:
a first CMOS transistor pair including a first PMOS transistor and a first NMOS transistor electrically connected at a drain coupling;
a second CMOS transistor pair including a second PMOS transistor and a second NMOS transistor electrically connected at a drain coupling, the second CMOS pair being arranged in parallel with the first CMOS pair such that a source of the first PMOS transistor is electrically coupled to a source of the second PMOS transistor, and a source of the first NMOS transistor is electrically coupled to a source of the second NMOS transistor and to a ground reference voltage;
a current source transistor electrically coupled between a supply voltage and the sources of the PMOS transistors, such that a control voltage applied to the current source transistor controls current flowing through the transistor pairs in the CMOS configuration;
wherein:
(a) the first input is electrically coupled to the drain coupling of the first transistor pair;
(b) the second input is electrically coupled to the drain coupling of the second transistor pair;
(c) gates of the first PMOS transistor and the second PMOS transistor are capacitively cross-coupled with the first input and the second input;
(d) gates of the first NMOS transistor and the second NMOS transistor are capacitively cross-coupled with the first input and the second input;
(e) a first control voltage biases the first PMOS transistor through a first bias resistor, and the first control voltage biases the second PMOS transistor through a second bias resistor;
(f) a second control voltage biases the first NMOS transistor through a first bias resistor, and the second control voltage biases the second NMOS transistor through a second bias resistor;
(g) each of the first and second PMOS transistors and the first and second NMOS transistor includes a gate capacitively coupled to the ground reference voltage.

34. A circuit according to claim 33, wherein the current source transistor is electrically coupled between the sources of the NMOS transistors and a ground reference voltage, and the supply voltage is electrically coupled to the sources of the PMOS transistors.

35. An apparatus comprising:
a resonator circuit including at least an inductor and a capacitor;
an optimizing circuit for providing a negative resistance, wherein the optimizing circuit (i) is electrically coupled to the resonator circuit, (ii) includes at least two PMOS transistors or two NMOS transistors electrically coupled to the resonator circuit through capacitors, and (iii) receives at least one control voltage for selectively biasing one or more of the transistors and varying the negative resistance.
a Q measuring circuit electrically coupled to the resonator circuit for measuring a quality factor associated with the resonator circuit and for producing a quality factor signal corresponding to the quality factor; and,
a controller circuit for receiving the quality factor signal and a reference Q signal, and producing the at least one control voltage therefrom, so as to adjust a quality factor Q associated with the resonator circuit commensurate with the reference Q signal.
